(19) United States
(12) Patent Application Publication
(10) Pub. No.: US 2009/0115434 A1
(43) Pub. Date: May 7, 2009

(54) Sample Cell for Hand-Held Impedance Spectroscopy Device

(76) Inventors: Richard W. Hirthe, Milwaukee, WI (US); Robert P. Adikes, Whitefish Bay, WI (US); Michael M. Bohacheck, Belgium, WI (US); Charles J. Koehler, III, Milwaukee, WI (US); Douglas F. Tomlinson, Waunakee, WI (US); Martin A. Seitz, Brookfield, WI (US)

Correspondence Address: WHYTE HIRSCHBOECK DUDEK S.C.;INTELLECTUAL PROPERTY DEPARTMENT, 33 East Main Street, Suite 300, Madison, WI, 53703-4655, US

(21) Appl. No.: 12/263,064

(22) Filed: Oct. 31, 2008

Related U.S. Application Data
(60) Provisional application No. 60/985,120, filed on Nov. 2, 2007.
(60) Provisional application No. 60/985,127, filed on Nov. 2, 2007.
(60) Provisional application No. 60/985,134, filed on Nov. 2, 2007.

(51) Int. Cl. G01R 27/08

(52) U.S. Cl. 324/693

(57) ABSTRACT

Disclosed herein is a sample cell for use in conjunction with an impedance spectroscopy analysis device having two electrodes extending therefrom. The sample cell is attachable to and detachable from the analysis device and includes a housing having an input port for receiving a fluid sample to be tested. The sample cell also includes two spaced apart parallel plates within the housing and in contact with the fluid sample, wherein when the sample cell is attached to the analysis device, each of the two electrodes contacts a respective one of the plates such that an excitation signal can be provided from the analysis device via the electrodes and the plates to excite the fluid sample, and a response signal indicative of the fluid sample can be communicated via the plates and the electrodes to the analysis device.

### CROSS-REFERENCE TO RELATED APPLICATIONS

This application claims priority to U.S. provisional patent application Ser. Nos. 60/985,120; 60/985,127, and 60/985,134, all filed on Nov. 2, 2007.

### FIELD OF THE INVENTION

The present invention relates to a sample cell which provides a reservoir for holding a sample of fluid to be tested using a device that employs impedance spectroscopy (IS) for analyzing fluids.

### BACKGROUND OF THE INVENTION

Increasing consumption of fossil fuels is occurring on a worldwide basis. Many countries rely on fossil fuel use to the detriment of society and ecosystems. Reduction in the amount of fossil fuel consumption and increased use of bio-based fuels has become an increasingly important initiative for consumers and governments alike. In particular, the increased use of biodiesel is lauded as an important step in the direction of reducing fossil fuel consumption. However, the transition to including biodiesel in everyday fuel has created a series of problems to both diesel consumers and combustion engine manufacturers. A key problem surrounds determining the concentration of biofuel, often referred to as fatty acid methyl ester (FAME), within a blended biodiesel sample. Identification of other alkyl esters is contemplated by this invention.

Biodiesel is often defined as the monoalkyl esters of fatty acids from vegetable oils and animal fats. Neat and blended with conventional petroleum diesel fuel, biodiesel has seen significant use as an alternative diesel fuel. Biodiesel is often obtained from the neat vegetable oil transesterification with an alcohol, usually methanol (other short carbon atom chain alcohols may be used), in the presence if a catalyst, often a base. Various unwanted materials are found in biodiesel, which can include glycerol, residual alcohol, moisture, unreacted feedstock (triacylglycerides), monglycerides, diglycerides, and free (unreacted) fatty acids.

Biodiesel fuels are often blended compositions of diesel fuel and biomass, which is often esterified soy-bean oils, rapeseed oils or various other vegetable oils. It is the similar physical and combustible properties to diesel fuel that has allowed the development of biofuels as an energy source for combustion engines. However, biofuels are not a perfect replacement for diesel. By example, the conversion quality, oxidation stability and corrosion potential of these biofuels present a concern to continued consumption as a viable fuel. Based upon these issues, as well as others known to one skilled in the art, careful control of the biofuel concentration must be implemented.

Beyond the physical and chemical concerns, monetary concerns exist. The United States government provides a tax credit for biofuel consumption. The tax credit is based upon the biofuel percentage within a biodiesel blend. In fact, the tax credit can be substantially different for a slight change in the percentage, since $0.01 per FAME percentage per gallon used is provided by the government. Therefore the difference between 20% and 25% FAME in biodiesel fuel can result in a considerable tax value. Often it is the case that biodiesel blends are “splash-blended”, which refers to the liquid agitation that occurs as the fuel truck is driving on the road after the diesel and biofuel have been combined. “Splash-blended” biodiesel blends often have a blend variance of up to 5%, which is unacceptable.

Various methods and technologies have been employed to determine the biofuel percentage within a biodiesel blend. These methods include gas chromatography (GC), fourier transform infrared (FTIR) spectroscopy, and near-infrared (NIR) spectroscopy. None of these methods provide a portable, quick and accurate determination of the FAME percentage within a biodiesel blend.

It would be advantageous to have a system and method for quickly and accurately determining the concentration of biodiesel fuel blends for use in quality control, production testing and distribution testing.

### BRIEF DESCRIPTION OF THE DRAWINGS

FIG. 1 is a block diagram of the fuel analyzer system in accordance with at least one embodiment of the invention;

FIG. 2 is a block diagram of a logic controller in accordance with at least one embodiment of the invention;

FIG. 3 is an alternative embodiment of the fuel analyzer system in accordance with at least one embodiment of the invention;

FIG. 4 is a flow chart representing a method for analyzing biodiesel blends in accordance with at least one embodiment of the invention;

FIG. 5 is a FTIR spectra for biodiesel concentration;

FIG. 6 is a Beer's Law FTIR model for biodiesel concentration standards;

FIG. 7 is a room temperature impedance spectra for biodiesel standards;

FIG. 8 is an impedance spectroscopy model for biodiesel concentration standards;

FIG. 9 is a test data table including both FTIR and impedance spectroscopy data;

FIG. 10 is a biodiesel method comparison data plot;

FIG. 11 is a biodiesel method residuals data plot;

FIG. 12 is an alternative embodiment of the impedance spectroscopy data analyzer in accordance with at least one embodiment of the present invention;

FIG. 13 is a measured form calculation sequence;

FIG. 14 is a Complex Plane Representation mathematical sequence;

FIG. 15 is an impedance and modulus plot sequence;

FIG. 16 is a biodiesel modulus spectra plot;

FIG. 17 is an impedance spectroscopy derived model data plot;

FIG. 18 is a block and wiring diagram of an exemplary hand-held analyzer device, in accordance with at least some embodiments of the present invention;

FIG. 19 is a partially exploded front perspective view of the exemplary hand-held analyzer device illustrated in block diagram form in FIG. 18, in accordance with at least some embodiments of the present invention;

FIG. 20(a) is a perspective view of an exemplary sample cell, in accordance with at least some aspects of the present invention;

FIG. 20(b) is an exploded perspective view of the exemplary sample cell of FIG. 20(a);

FIGS. 20(c)-20(f) are, respectively, a top view, a front view, a side view, and a bottom view of the exemplary sample cell of FIG. 20(a);

FIG. 21 is an exploded front perspective view of an exemplary shroud assembly of the hand-held analyzer device of FIG. 19;

FIGS. 22(a)-(c) are various views of the shroud assembly of FIG. 21;

FIG. 23 is an exploded front perspective view of an exemplary top cover assembly of the hand-held analyzer device of FIG. 19; and

FIG. 24 is a circuit diagram of an exemplary sample cell circuit, in accordance with at least some embodiments of the present invention.

### DETAILED DESCRIPTION

Biodiesel includes fuels comprised of short chain, mono-alkyl, preferably methyl, esters of long chain fatty acids derived from vegetable oils or animal fats. Short carbon atom chain alkyl esters have from e.g., 1 to 6 carbon atoms, preferably 1 to 4 carbon atoms and most preferably 1 to 3 carbon atoms. Biodiesel is also identified as B100, the “100” representing that 100% of the content is biodiesel. Biodiesel blends include a combination of both petroleum-based diesel fuel and biodiesel fuel. Typical biodiesel blends include B5 and B20, which are 5% and 20% biodiesel respectively, Diesel fuel is often defined as a middle petroleum distillate fuel.

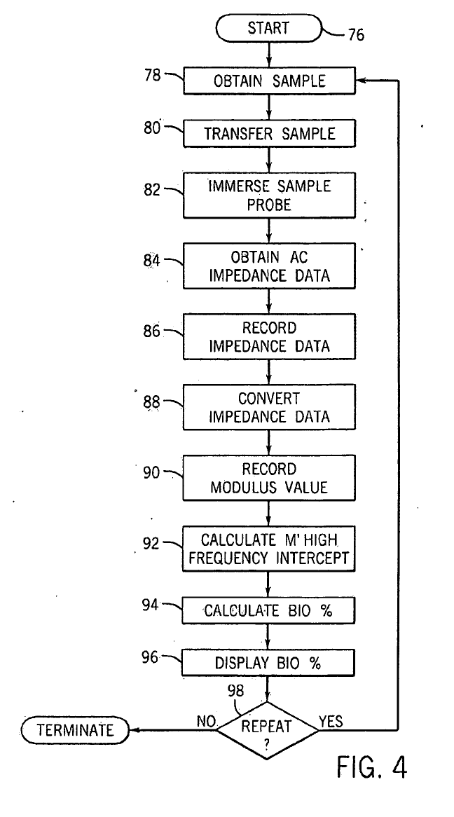

Now referring to FIG. 1, an illustrative example of the system 10 in accordance with at least one embodiment of the invention includes an analysis device 12, graphical user interface (GUI) 14, memory storage device 16, probe 18, and reservoir 20. The analysis device 12 includes a logic controller 22, a memory storage device 24, a modulus converter 26 and an impedance converter 28. The reservoir 20 contains a biofuel sample, which can be selected from the group including a biodiesel blend, heating fuel, second phase materials, fuel additives, methanol, glycerol, residual alcohol, moisture, unreacted feedstock (triacylglycerides), monoglycerides, diglycerides, and free (unreacted) fatty acids. The probe 18 is external and separately connected to the reservoir 20 and can alternatively be integrated within the reservoir 20. The probe 18 provides inputs to the reservoir 20 through input/output line 30. Excitation voltage (V_{(f)}) is applied to the reservoir from probe 18 and a response current (I_{(f)}) over a range of frequencies is measured and provided to the analysis device 12. The impedance data is analyzed and converted by the impedance converter 28, and then transferred to the modulus converter 26. The impedance data includes Zᵣₑₐₗ, Z_{imaginary}, and frequency. The modulus data includes Mᵣₑₐₗ, M_{imaginary}, and frequency. The logic controller 22 operates the modulus converter 26 and impedance converter 28 to store the respective data, including the impedance measurements, within memory storage device 24. The logic controller performs a computer readable function, which is accessed from memory storage device 24 that performs an impedance spectroscopy analysis method (See FIG. 4) and provides a biodiesel concentration to the GUI 14. The concentration data can be provided in the form of Bxx, where “xx” represents the concentration of the sample tested that is biofuel (biomass/FAME) in percentage of biodiesel. Concentration and percentage are often used interchangeably to describe the amount of biodiesel within a blended sample.

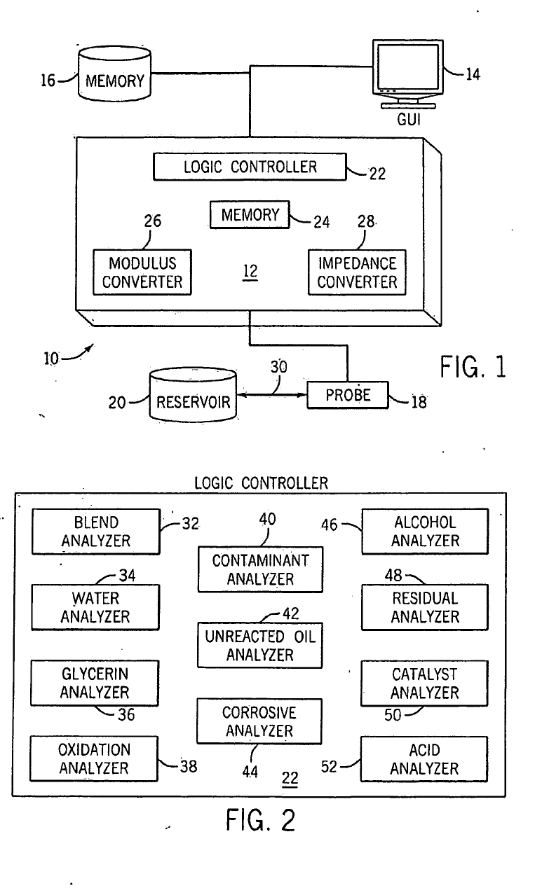

Referring to FIG. 2, an alternative embodiment of the logic controller 22 is illustrated. The logic controller 22 includes a blend concentration analyzer 32, a water analyzer 34, a glycerin analyzer 36, an oxidation analyzer 38, a contaminant analyzer 40, and unreacted oil analyzer 42, a corrosive analyzer 44, an alcohol analyzer 46, a residual process chemistry analyzer 48, a catalyst analyzer 50, and a total acid number analyzer 52. The water analyzer 34 performs analysis on the impedance data obtained from probe 18. The logic controller 22 accesses a computer readable function accessed from memory storage device 24 and provides information such as the presence of water, and if identified within the sample, the concentration of water within the sample. The glycerin analyzer 36 performs analysis on the impedance data obtained from probe 18. The logic controller 22 accesses a computer readable function accessed from memory storage device 24 and provides information such as the presence of glycerin, and if identified within the sample, the concentration of glycerin within the sample. Alternatively, the computer readable function is accessed from memory 16. In an alternative embodiment, a viscosity analyzer (not shown), and cetane number analyzer (not shown) are included for providing viscosity data and cetane number data for a fuel sample. In yet another alternative embodiment, a sludge/wax analyzer (not shown) are included for providing information on the presence and amount of sludge and/or wax precipitation within a fuel sample.

The oxidation analyzer 38 performs analysis on the impedance data obtained from probe 18. The logic controller 22 accesses a computer readable function accessed from memory storage device 24 and provides information such as the presence of oxidation. The contaminant analyzer 40 performs analysis on the impedance data obtained from probe 18. The logic controller 22 accesses a computer readable function accessed from memory storage device 24 and provides information such as the presence of contaminants, and identification of the type of contaminants within the sample, as well as the concentration of the particular contaminant within the sample. A variety of contaminants can be found within fuel samples, which include water, wax/sludge, and residual process chemistry.

The unreacted oil analyzer 42 performs analysis on the impedance data obtained from probe 18. The logic controller 22 accesses a computer readable function from memory storage device 24 and provides information such as the presence of unreacted oils, as well as the concentration within the sample. A variety of unreacted oil can be found within fuel samples, which include unreacted feedstock (triacylglycerides), monoglycerides, diglycerides, and free (unreacted) fatty acids.

The corrosive analyzer 44 performs analysis on the impedance data obtained from probe 18. The logic controller 22 accesses a computer readable function from memory storage device 24 and provides information such as the presence of corrosives, as well as the reactivity of the corrosive substances within the sample.

The alcohol analyzer 46 performs analysis on the impedance data obtained from probe 18. The logic controller 22 accesses a computer readable function from memory storage device 24 and provides information such as the presence of alcohol, and if present, the concentration of alcohol within the sample. The residual analyzer 48 performs analysis on the impedance data obtained from probe 18. The logic controller 22 accesses a computer readable function memory storage device 24 and provides information such as the presence of residuals, and identification of the type of residuals within the sample, as well as the concentration of the residuals within the sample. A variety of residuals can be found within fuel samples, which include alcohol, catalyst, glycerin and unreacted oil.

The catalyst analyzer 50 performs analysis on the impedance data obtained from probe 18. The logic controller 22 accesses a computer readable function from memory storage device 24 and provides information such as the presence of catalysts, as well as the concentration of the catalysts within the sample. A variety of catalysts can be found within fuel samples, which include KOH and NaOH. The total acid number analyzer 52 performs analysis on the impedance data obtained from probe 18. The logic controller 22 accesses a computer readable function from memory storage device 24 and provides information such as the presence of acids, as well as the concentration of the acids within the sample. A variety of acids can be found within fuel samples, which include carboxylic acid and sulfuric acid.

In an alternative embodiment, a stability analyzer (not shown) is provided. The stability analyzer performs analysis on the impedance data obtained from probe 18. The logic controller 22 accesses a computer readable function accessed from memory storage device 24 and provides information such as a stability value. Recent research has found that changes to the biodiesel element of biodiesel blends can have a deleterious effect upon the stability of the fuel sample over time. Blended samples that are left inactive for extended periods of time can potentially lose stability. The impedance spectroscopy data and stability analyzer function of this invention can provide information as to the sample's stability and efficacy.

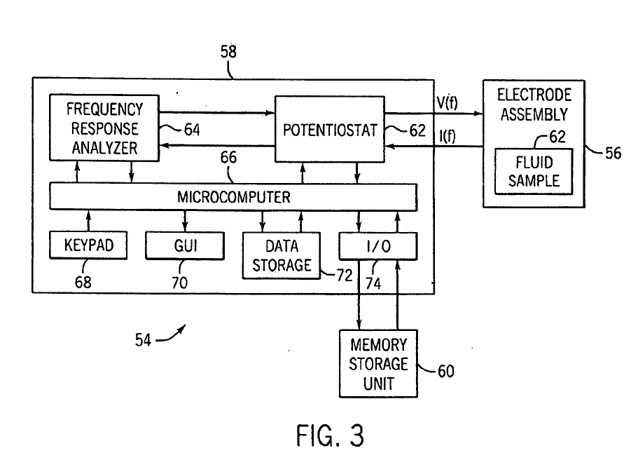

Referring to FIG. 3, an alternative embodiment of the impedance spectroscopy analyzing system 54, which includes an electrode assembly 56, a data analyzer 58, and a memory storage unit 60 is provided. The electrode assembly 56 includes a fluid sample 62 and probes (not shown). The data analyzer 58 includes a potentiostat 63, a frequency response analyzer 64, a microcomputer 66, a keypad 68, a GUI (graphical user interface) 70, data storage device 72, and I/O device 74. Impedance data is obtained from the electrode assembly 56 and input into the analyzer 58. The potentiostat 63 and frequency response analyzer together perform the impedance spectroscopy analysis methods (See FIG. 4). The microcomputer 66 accesses the computer readable functions from the memory storage unit 60 or the data storage device 72, and provide biofuel analyzed data to the GUI 70

Referring to FIG. 4, a flow chart is provided representing a method for determining the concentration of biodiesel (e.g., biomass/FAME content) in a blended biodiesel fuel sample in accordance with at least one embodiment of the present invention. The system 10 is initiated at step 76. A sample of the blended biodiesel is obtained at step 78 and then transferred to a clean container or reservoir at step 80. The sample is maintained at substantially room temperature, generally between about 60° F. and about 85° F. Alternatively, the sample is located in a vehicle fuel tank on board a vehicle or deployed “in-line” e.g., in a biodiesel synthesis plant. Measurement probes are cleaned and immersed within the reservoir at step 82. Alternatively, probes can be maintained within the reservoir and the fuel sample is added to the reservoir with the probes already within the reservoir. The probes can be self-cleaning probes. The impedance device is initiated and the AC impedance characteristics of the fuel sample are obtained at step 84. The frequency range extends from about 10 milliHertz to about 100 kHertz, or alternatively appropriate frequencies. The impedance data is recorded at step 86. The data can be saved in a memory device integral to the device 12. Alternatively, the impedance data is saved in an external memory device. The external memory device 16 can be a relational database or a computer memory module. At step 88, the impedance data is converted to complex modulus values. The complex modulus values are recorded at step 90. M′ high frequency intercept values are determined at step 92 from the complex modulus values and the biodiesel concentration is calculated at step 94. By example, Equation Set 1 is a linear algorithm used for calculating the biodiesel blend concentration. The biodiesel concentration value is represented on a user interface at step 96. If the process continues step 78 is repeated at 98, otherwise the sequence is terminated at step 100. One skilled in the art would recognize that there are chemical differences between biodiesel and petroleum-based diesel for which the present invention can be employed.

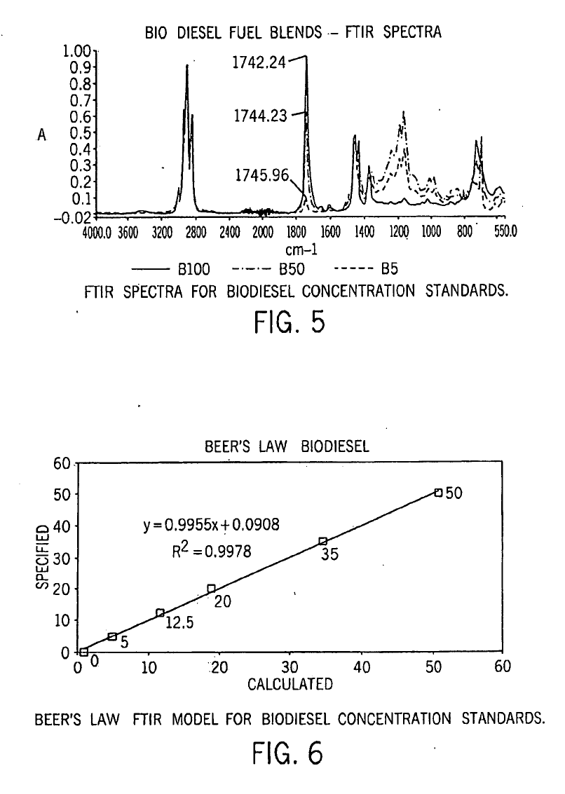

The Fourier transform infrared (FTIR) spectra analysis of three biodiesel concentration is provided in FIG. 5. Samples of B100, B50, and B5 were tested using an FTIR process. The FTIR process used for data obtained in FIG. 5 was modeled after the AFNOR NF FN 14078 (July 2004) method, titled “Liquid petroleum products—Determination of fatty acid methyl esters (FAME) in middle distillates—Infrared spectroscopy method.” Biodiesel fuel samples were diluted in cyclohexane to a final analysis concentration of about 0% to about 1.14% biofuel. This was to produce a carbonyl peak intensity that ranged between about 0.1 to about 1.1 Abs, using a 0.5 mm cell pathlength. The method showed a 44 g/l sample (B5 sample was diluted to 0.5%) having 0.5 Abs carbonyl peak height. The method recommended 5-standards be prepared ranging from about 1 g/l (about 0.11% biofuel) to about 10 g/l (about 1.14% biofuel).

The peak height of the carbonyl peak at or near 1245 cm⁻¹ was measured to a baseline drawn between about 1820 cm⁻¹ to about 1670 cm⁻¹. This peak height was used with a Beer's Law plot of absorbance versus concentration to develop a calibration curve for unknown calculation.

The modifications made to this method included no sample dilution, an ATR cell and utilization of peak area calculations. Sample dilution with cyclohexane is a very large source of errors. The reasons to dilute the sample include reducing the viscosity for flow (transmission cell), opacity or to maintain the absorption peak height of the sample with the detector linearity. The detector linearity of the instrument used was in the range of about 0 Abs to about 2.0 Abs. By reducing the cell pathlength to about 0.018 mm the absorbance of a B100 sample was about 1.0 Abs. This allowed dilution to be unnecessary. The use of a UATR cell allowed a very controlled and fixed pathlength to be maintained.

The peak of interest demonstrated migration during dilution due to solvent interaction, evidenced in the biofuel spectra shown in FIG. 5. As a result, the peak area was chosen as the measurement technique. In addition, peak area is the preferred technique for samples that contain multiple types of a defined chemistry type, such as that found in biofuels. Substances found in biofuels that are distinguishable from one another and from petroleum-based fuels constituents by means of impedance spectroscopy are, of course, a focus of this invention. Exemplary substances include saturated and unsaturated esters. The result of Beer's Law calibration is shown in FIG. 6. The biofuel samples were measured against the calibration curve of FIG. 6. The impedance spectroscopy methods were measured against this FTIR process.

y=−3.371E+07x+8.158E+09, Equation Set 1
where y=M′ and x=% biodiesel

At least one embodiment of the present invention was tested for feasibility by comparison with FTIR analysis, an industry accepted test method, of biodiesel fuel blend concentration. The blend samples that were tested included B50, B20 and B5. The samples were evaluated using both broad spectrum AC impedance spectroscopy as well as FTIR spectroscopy. Additionally, the blends of unknown values were tested to determine the impedance data using impedance spectroscopy. Conventional diesel fuel and a variety of nominal blend ratios were used as test standards.

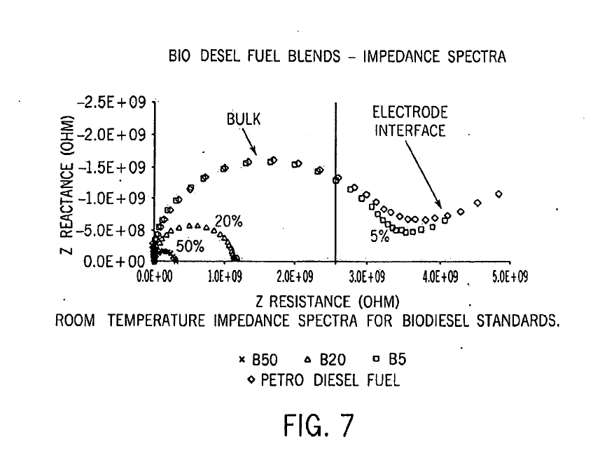

Approximately 20 mL samples of each biodiesel blend were evaluated at room temperature utilizing a two (2) probe measurement configuration. FIG. 7 provides an example of the impedance spectra in a line plot configuration, with reactance (ohm) plotted against resistance (ohm). The impedance spectra provide a clear distinction between B50, B20, B5, and petroleum diesel fuel. Generally the impedance at given frequency, ω, contains two contributions as shown in Equation Set 2. More specifically, FIG. 7 provides the resistance (Rₛ) plotted against the Reactance (1/ωCₛ), which provides an indication that the resistivity of the biodiesel blend sample is sensitive to the percent biodiesel within the base diesel fuel. As a result, the impedance spectra can be used to identify the concentration percentage of biodiesel within a biodiesel blend sample.

Z*(ω)=Rₛ−j(1/ωCₛ) Equation Set 2

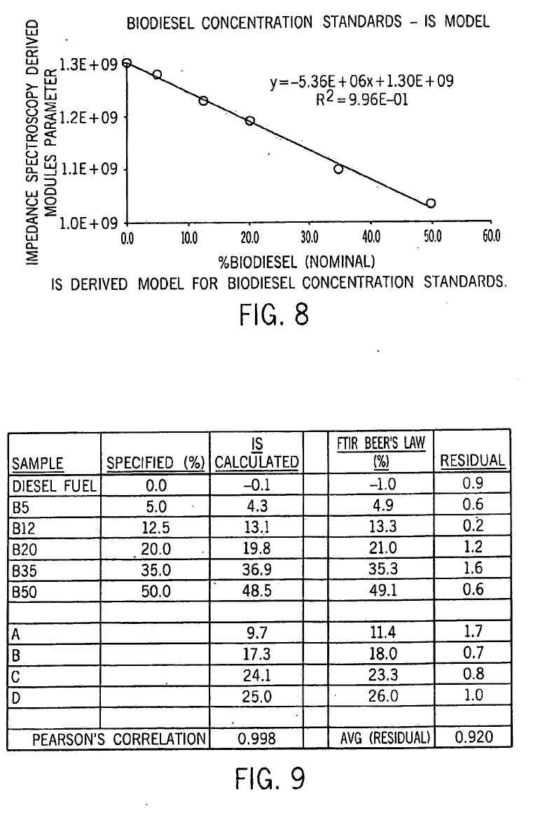

Further manipulation of the impedance data indicates that the polarizability of the blended biodiesel sample is systematically impacted as the concentration of biodiesel increases or decreases. Therefore, a real modulus representation value can be calculated. This presents a parameter, for which a correlation can be made. A correlation between the measured impedance-derived spectra data and the stated biodiesel percentage concentration value can be established. The correlation is graphically presented in FIG. 8, where the impedance derived modulus parameter is plotted against the biodiesel concentration. A linear relationship having a negative slope is provided. These results provide an indication that a correlation similar to that of the industry accepted FTIR method is feasible for impedance spectroscopy.

Referring to FIG. 9, a test data table is provided. The table includes known biodiesel standards, including pure petroleum diesel fuel, B5, B12, B20, B35, and B50. Each of these standards (Reference Standards) was tested using the FTIR process and the impedance spectroscopy process of the present embodiment. The results for each of these tests are provided in the table. Additionally there are four unknowns, A, B, C, and D (Unknown Blend Set 1), for which test results were obtained using both the FTIR process and the impedance spectroscopy process of the present embodiment.

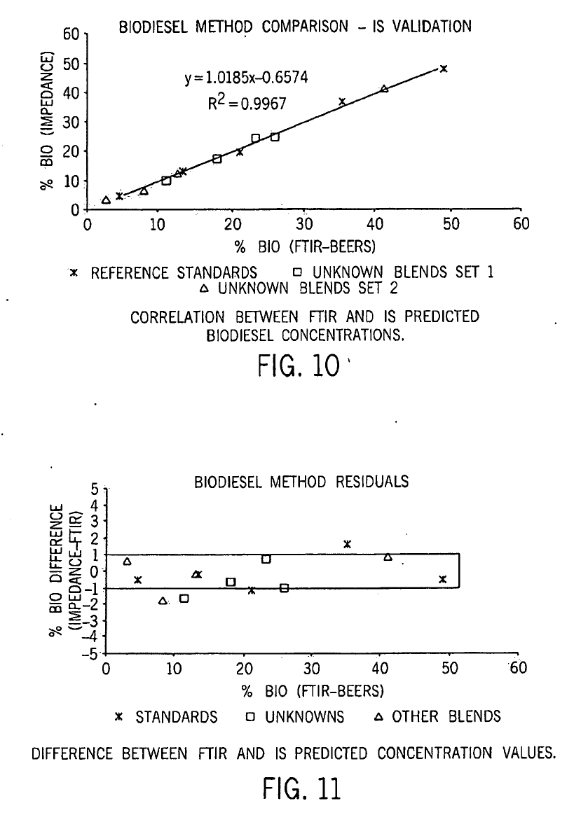

Referring to FIG. 10, the test data provided in FIG. 9 is presented in the form of a X-Y plot. The biodiesel concentration data obtained from the impedance spectroscopy process is plotted against the biodiesel concentration data obtained from the FTIR process. A correlation line is fit to the data points, which indicates a close correlation between the two methods for determining biodiesel concentration. Additionally, a second set of unknown biodiesel blends (Unknown Blends Set 2) were tested through both stated processes. These unknown blends were prepared by blending B100 and two separate petroleum fuels. These data points are not provided in FIG. 9, but are plotted in FIG. 10.

A scientifically significant agreement between the FTIR process and the impedance spectroscopy process of the present embodiment was found. This is evidenced by the line fit assigned to the plotted data points. Residual values (% bio_{FTIR}−% bio_{Impedance}) were calculated and provided in FIG. 9. The average residual value is 0.920, which is less than 1.0%, presenting a highly significant linear correlation between the widely accepted FTIR process and the impedance spectroscopy process of the present embodiment. The difference between the FTIR process and the impedance spectroscopy process of the present embodiment are presented in FIG. 11.

The system 10 can be implemented in the form of a low cost, portable device for determining real-time evaluation of biodiesel blends. The device provides the user with blended FAME concentration in order for the user to compare with established specifications. Furthermore, the device enables the user to detect contaminants and unwanted materials within the biodiesel sample. The impedance spectroscopy data processing provides the user a broader functionality view of the biodiesel sample, and not simply the chemical make-up. Performance of the fuel can be affected by unwanted materials and detecting the presence of the unwanted materials the user is better able to make decisions that affect performance of the vehicle.

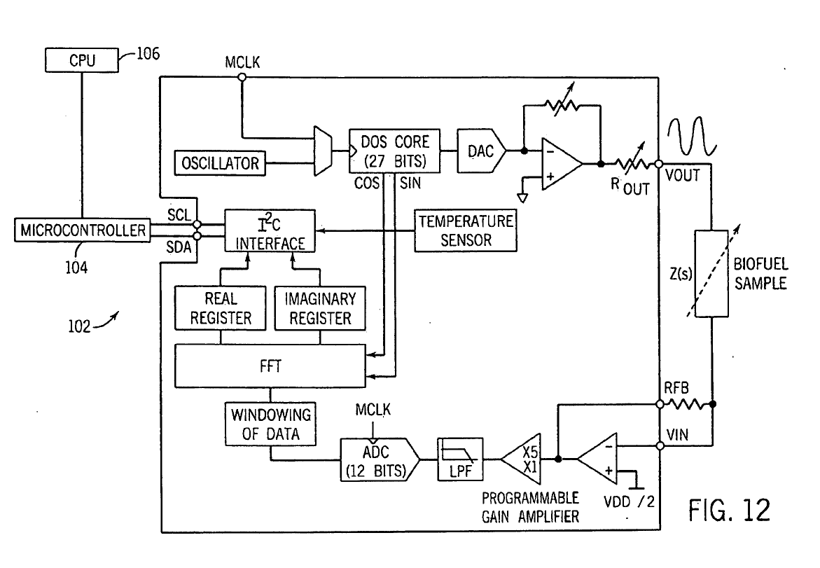

Another embodiment of the impedance spectroscopy system is shown in FIG. 12, which illustrates in block diagram form a portable, bench-top device 102. The biofuel sample can be tested external to the device 102, or alternatively internal to the device 102. A microcontroller 104 relays data to the central processing unit (CPU) 106 for calculation. Once the data has been calculated the biofuel concentration is sent to a graphical user interface (GUI) (not shown) by an I/O device (not shown). The device 102 has either an internal or external power source, as well as a suitable sampling fixture. The impedance data is acquired by the device 102 and transferred to the CPU for detection and identification, of elements within the sample as well as the relative concentrations of the elements. By example, the elements can include FAME, glycerol, residual alcohol, moisture, additives, corrosive compounds, unreacted feedstock (triacylglycerides), monglycerides, diglycerides, and free (unreacted) fatty acids.

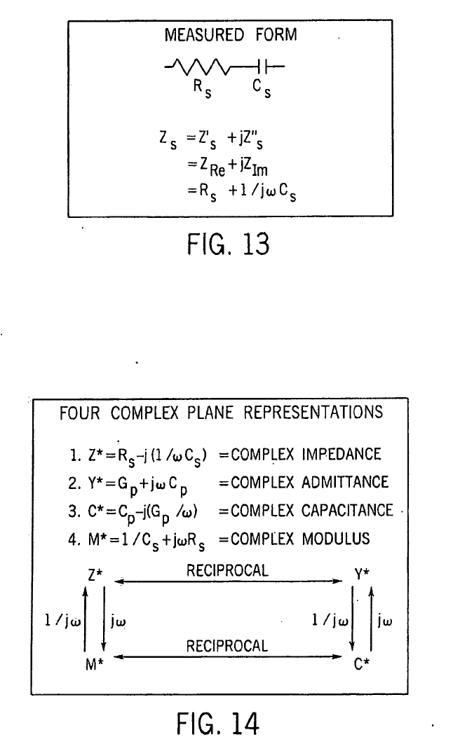

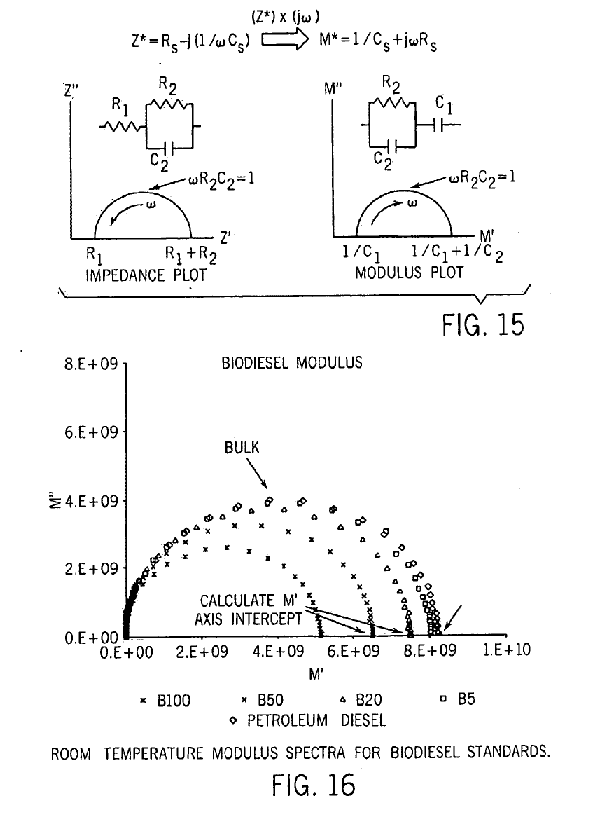

The biodiesel blend sample is tested and data is acquired by treating the sample as a series R—C combination. (See FIG. 13). The acquired sample data is converted by inversion of the weighting of the bulk media contribution to the total measured data response, wherein the value C₂ is typically a small value (See FIG. 14). This conversion minimizes the interfacial contribution of the bulk media, wherein the value C₁ is typically a large value (See FIG. 15). The real modulus transformation (M′) calculated for each biofuel sample is divided by the value (2*PI) in order to disguise the identity.

The biodiesel modulus spectra for the dedicated testing standards are provided in FIG. 16. The modulus data element M″ is plotted against the modulus data element M′. Data points for a petroleum diesel sample, as well as B5, B20, B50, and B100 were plotted. The complex impedance values (Z′) is converted to a complex modulus representation (M′) in order to inversely weight and isolate the bulk capacitance value from any interfacial polarization present within the sample. The M′ high frequency intercept via a semicircular fitting routine is then calculated.

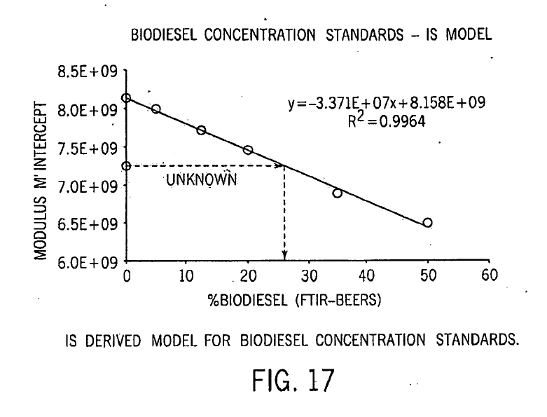

The biodiesel concentration standard, for which the impedance spectroscopy process will be measured against, is shown in FIG. 17. The previously calculated modulus (M′) intercept was plotted against the biodiesel concentration, as determined by the FTIR method. Equation Set 3 represents the derived algorithm.

y=−3.371E+07x+8.158E+09 Equation Set 3
where x=% biodiesel, and R²=0.9964

Biofuel samples are tested using the analyzer 12. The impedance data measurement is focused upon the biofuel sample while the electrode influence and probe fixturing are minimized.

In an alternative embodiment, fuel analyzer system 10 and methods of the present invention are used to determine the FAME concentration in heating fuel. The heating fuel sample is tested in a similar manner as that described for the biodiesel fuel blend. Alternatively, the system 10 can be used to analyze cutting fluids, engine coolants, heating oil (either petroleum diesel or biofuel) and hydrolysis of phosphate ester, which is used a hydraulic fluid (power transfer media).

In an alternative embodiment, the system 10 analyzes a biodiesel blend sample for the presence of substances selected from a group including second phase materials, fuel additives, glycerol, residual alcohol, moisture, unreacted feedstock (triacylglycerides), monglycerides, diglycerides, and free (unreacted) fatty acids. In yet another alternative embodiment, the system 10 analyzes a biodiesel blend sample for the concentration of substances selected from a group including second phase materials, fuel additives, methanol, glycerol, residual alcohol, moisture, unreacted feedstock (triacylglycerides), monoglycerides, diglycerides, and free (unreacted) fatty acids.

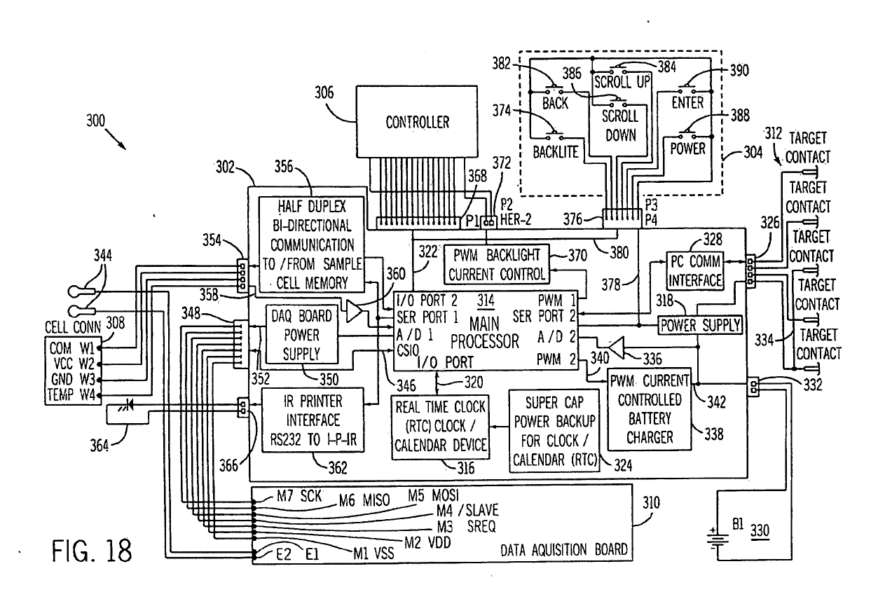

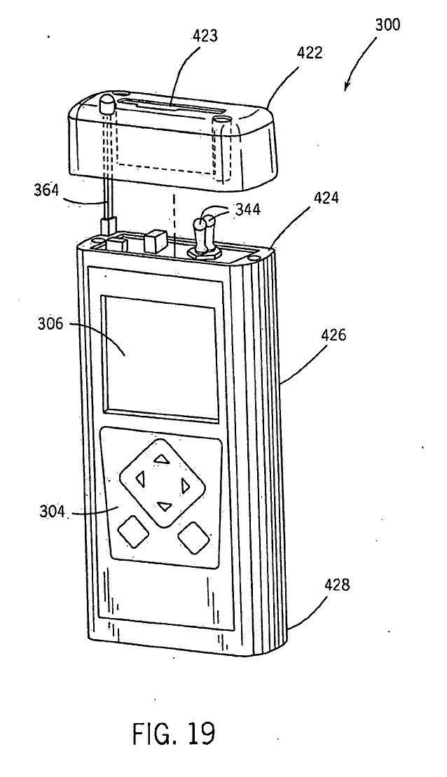

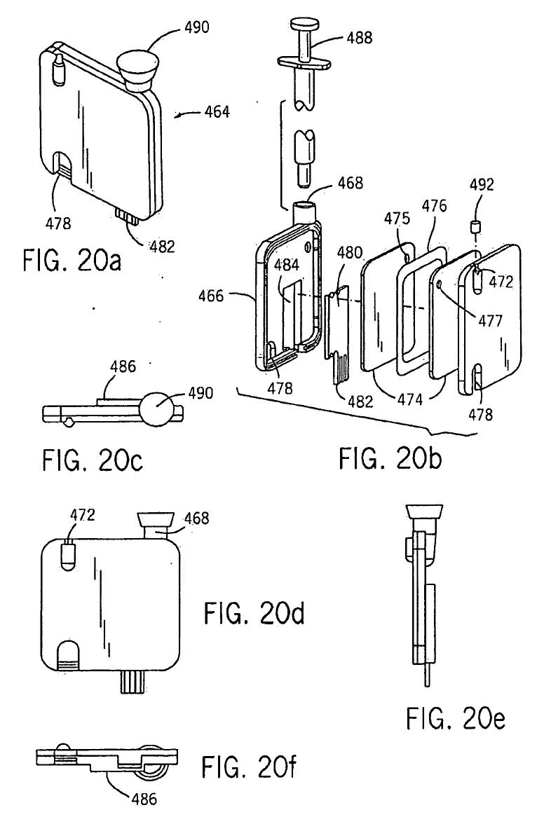

Another embodiment of an impedance spectroscopy system is illustrated in FIG. 19, which illustrates a perspective view of an exemplary hand-held impedance spectroscopy analysis device 300, which is operable with a sample cell, such as sample cell 464 illustrated in FIG. 20(a), to measure and analyze a fluid sample in accordance with methods similar to those discussed above to determine one or more fluid properties. The sample cell serves as a reservoir for the fluid sample, and is preferably a one-time use detachable device that can be plugged into and removed from a slot 423 of the hand-held analysis device 300. The fluid sample is preferably a fuel sample such as a blended biofuel sample. The fluid properties which can be determined by the device 300 preferably include one or more of a biofuel blend content or percentage, a total glycerin content or percentage, an acid number, and a methanol content or percentage. A block diagram of the hand-held analysis device 300 is illustrated in FIG. 18.

Referring to FIG. 18, the device 300 includes a processing system 302 in operable association with a keypad 304, a display 306, a data acquisition board (DAQ board) 310, a light emitting diode (LED) 364, a battery 330, and a plurality of target contacts 312. The processing system 302 is also in communication with a cell connection unit 308 for connecting to the sample cell 464, which contains the fluid sample to be tested and analyzed. With respect to the processing system 302 in particular, it is capable of processing a wide variety of information received from one or more of the aforementioned components (e.g., keypad 304, the sample cell via connection unit 308, etc.) to determine fuel sample properties and display the same via the display 306. Each of the keypad 304, the display 306, the cell connection unit 308, the DAQ board 310, and the plurality of target contacts 312 are connected to the processing system 302 by way of one or more plugs (also referred herein as contacts, pins or connection points), as will be described in more detail below.

Further, as shown in FIG. 18, the processing system 302 includes a main processor 314 for processing various types of information; a real time clock (RTC)-calendar and clock device 316 for keeping track of current date and time; a power supply 318 for providing variable voltages to the various components of the hand-held analysis device 300; and a plurality of communication interfaces for connecting the components (through respective plugs) to the main processor, as well as other components. With respect to the RTC calendar and clock device 316, it is connected to the main processor 314 at a first Input/Output (I/O) port (e.g., I/O port 1) via duplex communication links 320 for providing continuous display of the current date and time on the display 306. Additionally, to accurately keep track of current date and time even when the hand-held device 300 is powered off, the RTC calendar and clock device 316 is connected to a super cap power backup 324, which provides power to the RTC calendar and clock device when the hand-held device is turned off.

Power to the other components (e.g., keypad 304 and display 306) of the hand-held analysis device 300 is provided by the power supply 318. In particular, the power supply 318 receives a fixed voltage input and regulates the input voltage (in a known manner) to provide variable voltages for proper operation of the various components of device 300. Typically, the fixed voltage input power to the power supply 318 can be provided either via the target contacts 312 connected thereto through plugs 326 or through a battery 330 connected to the power supply through a plug 332. For example, a 12 Volt input from the target contacts 312 can be transformed into a 5 Volt power supply for powering the electronic circuitry of the main processor 314. Relatedly, a 3.3 Volt power supply can be generated for operation of the display 306. Similarly, variable voltages for the keypad 304, and other components of the hand-held device 300 are generated from the power supply 318.

With respect to the target contacts 312, in addition to being connected to the power supply 318, the target contacts are also connected to the main processor 314 for duplex communication therewith. Particularly, the target contacts 312 are connected to the main processor 314 at a serial port (e.g., Ser Port 2) via a PC communication interface 328 connected to the plugs 326. By virtue of providing the target contacts 312 connected to the main processor 314 and the power supply 318, the hand-held device 300 can be plugged into a charging base (not shown) and/or docking station (not shown) connected to a wall plug power supply (also not shown) for providing an input power to the power supply 318. When seated in the charging base (or docking station), the hand-held device 300 can be used for viewing (e.g., on display 306) and/or transferring stored results and/or data from the main processor 314 to another device. Notwithstanding the fact that five target contacts are shown in the present embodiment, this number can vary in other embodiments to include either less than five target contacts or potentially more than five as well.

The target contacts 312 are equipped with a safety/sensing mechanism for avoiding electrical shock to a user on contact with the target contacts. In at least some embodiments of the present invention, the target contacts are designed such that at least two of the target contacts are connected together to form a relay circuit. For example, as shown in the present embodiment, target contact 3 (TGT3) is connected to the target contact 5 (TGT 5) by communication link 334 to form a relay circuit. In normal operating conditions when the hand-held device 300 is removed from the charging base, the relay circuit is broken and, therefore, no current flows through the target contacts, preventing electric shock to the user. Upon seating the hand-held device 300 into the charging base, the relay circuit is closed by connection with the electrical contacts of the charging base and current through the target contacts flows for providing power to the power supply 318. Further, although in the present embodiment two target contacts are connected together to form the relay circuit, in other embodiments, more than two contacts can be connected together as well. Additionally, although one exemplary safety/sensing mechanism for avoiding electric shock has been described above, it is nevertheless an intention of this invention to encompass other mechanisms as well.

In addition to employing the target contacts 312 for providing input power to the power supply 318, the hand-held device 300 is also provided with the battery 330, which is preferably a rechargeable, replaceable battery connected to the power supply 318 of the processing system 302. The battery 330 is additionally connected to an analog-to-digital converter (e.g., A/D 2) port within the main processor 314 through an operational amplifier 336. By virtue of being connected to the power supply 318, the battery provides a source of input power for operating the hand-held device 300 when the device is not seated in the charging base. This allows measurements from the fluid sample to be obtained, and processing performed, when the hand-held device 300 is operating in the battery mode.

As indicated above, the battery 330 is preferably a rechargeable battery that can be recharged upon seating the hand-held device 300 in the charging base. In particular, when the hand-held device 300 is seated in the charging base, and power is supplied from the power supply 318 to the main processor 314 (e.g., through the target contacts 312), the battery 330 is recharged by pulse width modulated (PWM) current controlled battery charger 338, connected on one end to a PWM port (e.g., PWM 2) of the main processor (e.g., by exemplary communication link 340), and on the other end to the battery (e.g., by communication link 342). In at least some embodiments of the present invention, the battery 330 is a 7.2 V Lithium-Ion (Li-Ion) battery, although other voltages and types of batteries are also contemplated.

Referring still to FIG. 18, the data acquisition board (DAQ Board) 310 is utilized for exciting electrodes 344 and acquiring measurement data indicative of the fluid sample. The acquired measurement data, for example magnitude and phase data at a plurality of frequencies, is then sent to the processing system 302 for analysis. Specifically, to obtain data from a fluid sample, the DAQ board 310, at contacts points E1 and E2, is connected to the sample cell 464 shown in FIG. 20(a). More specifically, the DAQ board 310 is connected to two electrodes 344 of the hand-held device 300. As explained more fully below, when the sample cell 464 is inserted in the hand-held device 300, the electrodes 344 are in contact with two metal plates 474 of the sample cell, which are in contact with the fluid sample contained within the sample cell. In at least some embodiments, the metal plates are arranged in a parallel plate electrode configuration, with a Teflon layer or gasket between the metal plates. Thus, measurements corresponding to the fluid sample in the sample cell 464 can be obtained by excitation of the electrodes 344 which contact the metal plates 474 which contact the fluid sample in the sample cell.

In one embodiment, the DAQ board 310 is capable of providing a fixed excitation voltage to the electrodes 344, and measuring the current and phase angle of the fluid sample response relative to the excitation voltage. The process of applying an excitation voltage and measuring the resulting current and phase angle of the sample is repeated by varying the frequency of the voltage. For example, in at least some embodiments of the present invention, current and phase angle of the fluid sample relative to an excitation voltage can be measured for a plurality of frequencies, preferably approximately seven to ten different frequencies. In other embodiments, the number of and specific frequencies chosen can be varied. Further, in other embodiments for obtaining measurements, rather than applying a fixed excitation voltage, a fixed excitation current at varying frequencies can be applied and the resulting voltage and phase angle can be measured in at least some other embodiments for obtaining measurements. Further, the excitation voltage and/or excitation current need not be fixed. Rather, a varying current and/or voltage can be applied for exciting the fluid sample for data.

Subsequent to obtaining measurement data from the fluid sample, the DAQ board 310 communicates the sample measurement data to the main processor 314 for storage and processing. Particularly, the DAQ board 310 is connected to the main processor 314 at a CSIO port through a plug 348 and a duplex clocked (synchronous) serial I/O 346. Power to the DAQ board 310 is provided by the main processor 314 through a DAQ board power supply 350 connected at an analog-to-digital port (e.g., A/D 1) of the main processor. The DAQ board power supply 350 is additionally connected to the DAQ board 310 through the plug 348, as shown by a one-way communication link 352. By virtue of having a separate DAQ board power supply 350 for the DAQ board 310, power to the DAQ board can be turned off when the hand-held device 300 is not being used.

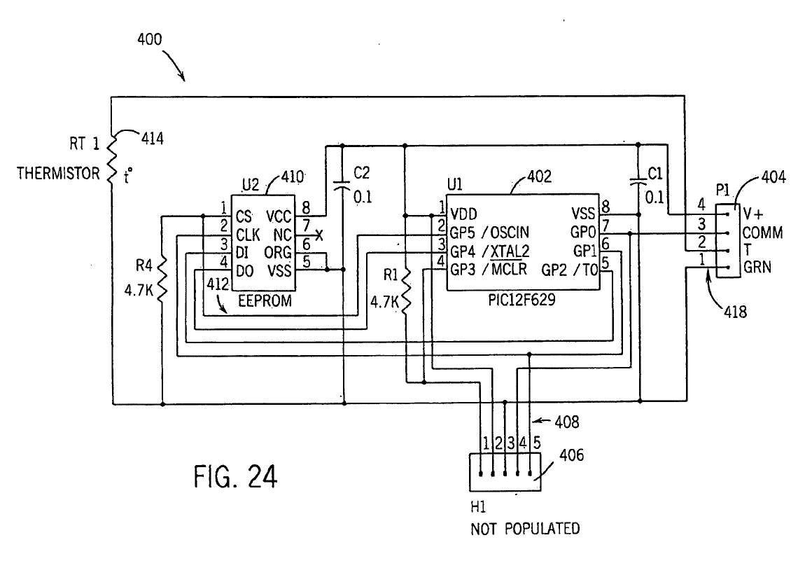

The main processor 314 is also in bi-directional communication with the sample cell when it is plugged into the hand-held device 300. In particular, a sample cell circuit (such as circuit 400 illustrated in FIG. 24) of the sample cell 464 is connected, via cell connection unit 308, plug 354, and circuit 356, to main processor 314. The sample cell circuit 400 includes a memory to store information such as an identifier and one or more calibration parameters relating to that sample cell. The sample cell memory is preferably a non-volatile memory capable of storing information even when the power to the sample cell is turned off. The memory is also preferably a memory which can be both read and written to. In at least some embodiments of the present invention, the memory can be configured as a removable memory device (e.g., a memory stick) that can be plugged and/or unplugged (e.g., via a Universal Serial Bus (USB) port) into the sample cell as desired.

In at least one embodiment, the sample cell memory can initially store a specific identifier, such as a serial number, which is unique to that sample cell. The main processor 314 is programmed to read the serial number and proceed with obtaining measurements only if that sample cell has not been previously used. In other words, the sample cell 464 is a one-time use device, and re-use of the sample cell can be prevented.

Typically, the stored calibration parameters are also specific to the sample cell 464 and relate to electrical characteristics of the dry (i.e. unfilled) sample cell, such as can be determined from impedance measurements of the dry sample cell at one or more frequencies for example. Thus, in addition to utilizing the measurement data corresponding to the fluid sample obtained by the DAQ board 310, the main processor 314 also reads the one or more calibration parameters from the sample cell memory and employs these parameters in the analysis of the fluid sample. Specifically, during operation, the one or more calibration parameters of the sample cell are provided to the main processor 314 via the cell connection unit 308, which is connected to the main processor via the plug 354 and half-duplex bi-directional communication interface 356. The half-duplex bi-directional communication interface 356 is additionally connected to the main processor 314 at a serial port (e.g., Ser Port 1) of the main processor.

In addition to calibration information, the main processor 314 preferably utilizes temperature information of the fluid sample in the determination of fluid sample properties, and produces results based upon the current temperature of the sample. Therefore, by virtue of determining the sample temperature and accounting for the temperature variations during processing, more accurate results can be obtained. In particular, temperature of the sample is obtained by a temperature sensor (such as thermistor 414 of FIG. 24) provided on or within the sample cell. The temperature sensor determines the approximate temperature of the fluid sample and transfers the temperature information through the cell connection unit 308 to the main processor 314. As shown, a separate voltage based temperature line 358 is connected to the A/D 1 port of the main processor 314 via an operational amplifier 360. Although in the embodiment illustrated in FIG. 18 the A/D 1 port is connected to both the DAQ board power supply 350 and the voltage based temperature line 358, in alternate embodiments, separate analog-to-digital ports can be utilized.

Upon collection of the calibration and temperature information from the sample cell 464 and the current and phase angle data of the sample fuel, the main processor 314 processes the information according to a stored algorithm, such as the algorithm explained above. In some embodiments, the processing system 302 and DAQ board 310 are programmed to determine one or more fluid sample properties using an improved algorithm which takes into account other variables, including for example the temperature of the sample and the calibration parameters mentioned above. Generally, such an improved algorithm can be developed using a data gathering technique in which a large set of data is gathered from various samples and then employing a data mining technique to statistically analyze the data set. For example, the data set can include impedance values at a given set of frequencies which are obtained for multiple biofuel samples having a range of different biodiesel concentrations. The samples each have an associated known value for the sample characteristic which can be obtained using another analytical method, which for a biodiesel blend concentration can be infrared spectroscopy for example. The other variables, such as temperature of the fluid sample, can also be measured or determined at the same time. Additional variables relating to spectral structural features for each sample can be determined. Then a data mining technique can be performed which eliminates co-variable or redundant information to determine relevant variables and then determines a relationship between the desired sample property and these relevant variables using the associated known values.

Once one or more of the fluid sample properties are determined, results can be stored in the main processor 314 and can also be sent via the half-duplex bidirectional communication interface 356 to the memory of the sample cell for additional storage. In one embodiment, both the calculated results (e.g., biodiesel concentration in the fluid sample) produced by the main processor 314 and the measured impedance data obtained by the DAC board 310 can be written to the memory of the sample cell in order to allow this data to be recovered from a used sample cell to be used to further fine-tune the data analysis algorithm for determining a fluid sample property. Further, any of the results, the calibration and temperature information, and the measurement data can be printed to a printer (not shown) via an Infra-Red (IR) printer interface 362 that is connected to the main processor 314 at the Ser Port 1.

Typically, the IR printer interface 362 employs a driver for converting RS232 ASCII code to the IR printer code, although other types of drivers can potentially be used. In at least some embodiments of the present invention, an HP 82240B IR printer available from the Hewlett-Packard Company of Palo Alto, Calif. is used. In alternate embodiments, printers other than the one mentioned above, can be used as well. Further, upon availability of results that can possibly be printed, the LED 364 is activated to signal to the printer the availability of the results. The photodiode is connected to the IR printer interface 362 via a plug 366. In addition to printing data on a printer, the present invention also provides the display 306, where results can alternatively be viewed.

With respect to the display 306, it is preferably a 128×128 pixel graphical LCD backlight display organized in eight lines of text, with each line capable of displaying 16 characters. In at least some embodiments, an Ampire Controller HD66750 display available from the Hitachi, Ltd of Marunouchi Itchome, Chiyoda, Tokyo, Japan is used. In alternate embodiments, displays other than the one mentioned above can be used as well. The display 306 is connected to the main processor 314 by way a plug 368 connected to the I/O port 2 of the main processor. The intensity (e.g., brightness) of the display 306 can be manipulated by way of a pulse width modulated (PWM) backlight current control 370 connected to a pulse width modulated port (e.g., PWM 1) of the main processor 314. The (PWM) backlight current control 370 is connected to a plug 372 that further connects to a plurality of Light-Emitting-Diodes (LED) on the display 306. By virtue of altering the current by the PWM backlight current control 370, the intensity of the backlight of the display 306 can be altered.

Further, the display 306 can be maneuvered by way of the keypad 304, which is provided with a plurality of buttons that can be depressed to power on/off the hand-held device 300 from the battery mode and/or maneuver the display 306. To achieve such functionality, the keypad 304 is connected to the main processor 314 and the display 306. For example, by virtue of a plug 376, the keypad 304 is connected to the main processor 314 via a communication link 378, and to the display 306 via a communication link 380. The keypad 304 is provided with a plurality of buttons, including, for example, a “BACK LITE button 374 for turning on/off the backlight of the display 306, a “BACK” button 382 to return to a previous display, and “SCROLL UP” and “SCROLL DOWN” buttons 384 and 386, respectively, for moving the display up and down. Also provided is a “POWER” button 388 to turn on/off the hand-held device 300 from the battery mode and an “ENTER” button 390 to move a cursor on the display 306 and/or display a new value. Notwithstanding the fact that six buttons have been described above with respect to the keypad 304, additional buttons providing additional functionality are contemplated in alternate embodiments.

Referring again to FIG. 19, the hand-held analyzer device 300 includes a shroud assembly 422, a top cover assembly 424, a case assembly 426 and a bottom cover assembly 428. As discussed more fully below, the shroud assembly 422 includes a slot 423 for receiving the sample cell. The case assembly 426 houses and protects most of the components shown in FIG. 18, including components such as the processing system 302 and the DAQ board 310 which are situated within the case assembly and including components such as the display 306 and keypad 304. The top cover assembly 424 acts as the interface between the sample cell and the processing system 302 and DAQ board 310, and includes the electrodes 344 which contact the metal plates 474 of the sample cell 464.

Referring now to FIGS. 20(a)-(f), exemplary sample cell 464 includes a housing formed by a first housing portion 466 having an input port 468 and a second housing portion 470 having an output port 472. The sample cell 464 also includes two spaced apart metal plates 474 within the housing separated by a gasket 476, preferably made of Teflon, wherein each metal plate has a respective through-hole 475, 477 formed therein. Each housing portion 466, 470 includes a cutout area 478 allowing access to a respective plate 474 by a respective electrode 344. The sample cell 464 also includes a printed circuit board 480 having a connection portion 482 extending out of the housing. The printed circuit board 480 supports and provides interconnections for a sample cell circuit, such as circuit 400 illustrated in FIG. 24. The first housing portion 466 includes a hollowed out portion 484 on the inside to accommodate the printed circuit board 480 and also includes a bumped out portion 486 on the outside.

A syringe 488 can be used to insert a fluid sample through the input port 468 into the sample cell. The fluid sample is directed via the input port 468 and through-hole 475 to a reservoir area formed between the two plates 474. The reservoir area is connected via through-hole 477 to the output port 472 on the second housing portion 470. The output port 472 allows for the escape of air as the sample cell is being filled and further allows a user to see when the sample cell has been filled. Respective caps 490, 492 can be provided to close the input port 468 and the output port 472 once the sample cell 464 is filled.

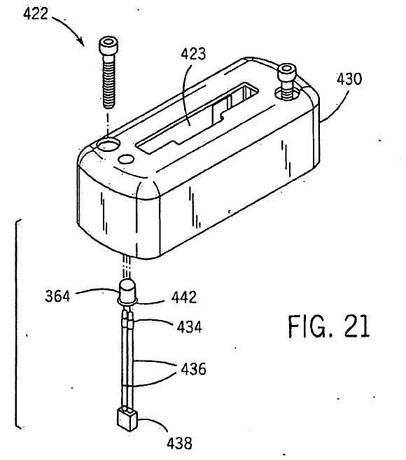

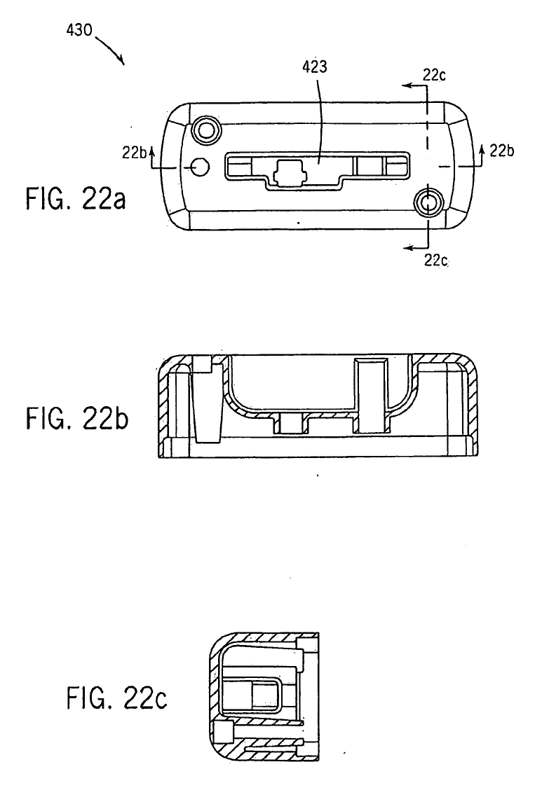

Turning to FIGS. 21 and 22(a)-(c), views of the exemplary shroud assembly 422 are illustrated, in accordance with at least some embodiments of the present invention. As shown, the shroud assembly 422 includes a shroud 430 having slot 423, the LED 364 of FIG. 18 supported on a shrink tube 434, wherein a flat surface 442 of the LED indicates a cathode portion. Wires 436 and connector 438 for connecting the shroud assembly to the top cover assembly 424 are also provided.

The shape of the slot 423 together with the bumped out portion 486 of the sample cell ensure that the sample cell is correctly oriented with respect to shroud assembly 422. In this manner, when the sample cell 464 is properly inserted in the device 300, the sample cell circuit 400 is in electrical communication with the processing system of device 300 and the electrodes 344 in contact with the metal plates.

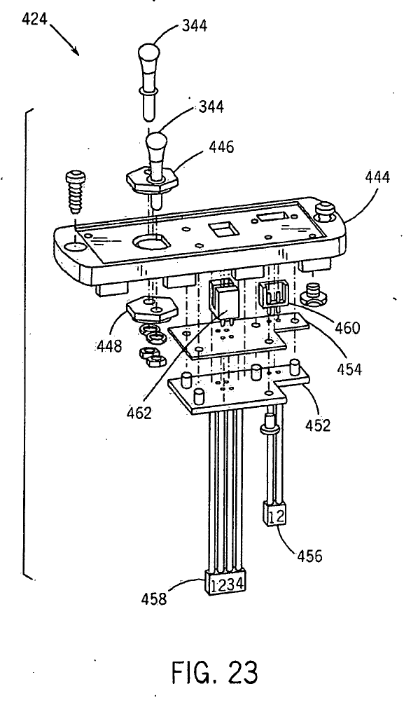

Referring now to FIG. 23, an exploded front perspective view of the top cover assembly 424 is shown, in accordance with at least some embodiments of the present invention. As shown, the top cover assembly 424 includes a top cover case 444 supporting an electrode grommet 446 and the pair of electrodes 344 of FIG. 18. When the sample cell is plugged into the device 300, each electrode 344 contacts a respective one of the metal plates 474 through a respective one of the cutout portions 478. Each electrode 344 preferably includes a bulbous portion on an outer end such that when the sample cell is inserted in the slot 423, the bulbous portions exert inward forces to tightly grip the metal plates and form good electrical contacts with the metal plates 474.

The top cover assembly 424 further includes an electrode spacer 448, a PCB top cover 452, a PCB top cover gasket 454, and first and second wire assemblies 456 and 458. Connectors 460 and 462 are also provided for facilitating connection between the sample cell 464 and the processing system 302.

Referring now to FIG. 24, exemplary sample cell circuit 400 of the sample cell 464 is shown, in accordance with at least some embodiments of the present invention. The sample cell circuit 400 preferably is formed as a printed circuit board assembly using the printed circuit board 480 housed in the sample cell 464. As shown, the sample cell circuit 400 includes a processor 402 and a memory module 410. The circuit 400 includes a connection unit 404 for electrical communication with the processing system 302 of FIG. 18 via connection with the cell connection unit 308 shown in FIG. 18 in order to convey information from the sample cell 464 to and from the main board 302. The sample cell circuit 400 further includes an additional pad 406, which in a preferred embodiment is not populated, but which in at least some embodiments can be employed for establishing additional connections, as indicated by a plurality of interconnect links 408.

With respect to the processor 402 in particular, in one aspect it operates as a data storage device that serves multiple purposes. To begin with, the processor 402 identifies the respective sample cell 464 by providing a serial number stored in a memory, such as an Electrically Erasable Programmable Read Only Memory (EEPROM) of the processor 402. By virtue of identifying the sample cell 464, multiple uses of that sample cell can be prevented. Generally speaking, the serial number is a unique number that identifies a sample cell such that upon being plugged into the device 300 and queried by the processing system 302, the sample cell can be identified as a new sample cell or an old sample cell (i.e., one that has previously been used), Any of a variety of other known techniques for providing single-use capability of a device can alternatively be used.

In addition, the memory of the processor 402 has stored therewithin calibration information relating to the sample cell 464. The calibration information is preferably provided to the processing system 302 via the cell connection unit 404 prior to excitation of the fluid sample, and provides information needed by the algorithm for calculating desired fluid properties such as the biofuel blend percentage. In at least some embodiments, the processor 402 can be a PIC12F629 CMOS flash-based 8-bit microcontroller having 128 bytes of EEPROM, available from the Microchip Technology, Inc. Company of Chandler, Ariz. In other embodiments, other similar microprocessors having memory capabilities to store serial, calibration and measurement information during testing can be employed as well.

Furthermore, the memory capabilities of the processor 402 can be expanded by way of employing additional memory module 410 in communication with the processor via a plurality of interconnect links 412. The memory device 410 can additionally be in communication with the pad 406. In at least some embodiments, the memory device 410 can be an EEPROM memory including, for example, a 1 Kbit 93C46A Serial EEPROM, available from the Microchip Company. In other embodiments, other types of memory devices capable of communicating with the processor 402 can be employed as well.

In addition to the processor 402 and the memory device 410, the sample cell circuit 400 also includes a thermistor 414 for measuring a temperature which is representative of the temperature of the fluid sample. Particularly, the thermistor is situated to measure the air in the space between the housing portion 466 and metal plate 474. The metal plates are assumed to be at approximately the same temperature as the air in this space. The metal plates are in contact with the fluid sample, so the temperature of the fluid sample is assumed to be approximately the same as the temperature measured by the thermistor. In at least some embodiments, a Panasonic ERT-J1VS104FA multilayer chip thermistor from the Matsushita Electric Industrial Co., Ltd. Company based in Kadoma, Osaka Prefecture, Japan, can be employed. In other embodiments, any of a wide variety of thermistors or other temperature sensors can also be employed.

One embodiment of the operation of the hand-held device 300 can be summarized as follows. As a first step, an unfilled sample cell 464 is plugged into the hand-held device, and the specific identification information corresponding to that sample cell and the calibration information (one or more calibration parameters) stored in the circuit 400 of the sample cell are downloaded to the processing system 302. In particular, data from the processor 402 is transmitted by way of a plurality of communication links 418 to the cell connection twit 404, which in turn conveys that information to the main board 302. Data stored in the memory device 410 can first be communicated to the processor 402 (e.g., via the interconnect links 412), which in turn can communicate that data to the main board 302 in the manner described above.

The processing system 302 then performs a check to ensure that the sample cell 464 has not been previously used. If the sample cell has not been previously used, then operation can proceed. The calibration parameters can be evaluated to ensure that they within respective predetermined ranges and/or additional measurements can be performed to measure these parameters and perhaps compare them to the initially stored parameters. The sample cell can then be filled with a sample fluid. The measurements of the impedance values at the selected number of frequencies and the temperature measurements can then be obtained. Specifically, the temperature measurements from the thermistor of the sample cell are transmitted via links 418 between the thermistor 414 and the pad 406. The sample fluid is excited with a plurality of voltage signals at varying frequencies via electrodes 344. A current response for each of the plurality of voltage signals is then measured and received by the DAQ board 310, then transmitted to the processing system 302 for storage and processing. The measurement data sent from the DAQ board 310 to the processing system can be in “raw” form, including complex impedance magnitude and phase data at each of a plurality of frequencies. The processing system 302 can then determine one or more desired fluid sample properties, such as a biofuel blend concentration. In one embodiment, the raw measurement data along with the processing results can also be sent to the sample cell circuit 400 to be stored in memory.

The sample cell 464 can then be recycled and returned to Paradigm Sensors. Any fluid sample remaining in the sample cell can be further tested using another analytical testing method. This result, along with the measurement data stored in the sample cell, can be added to the gathered data set, and additional data mining can be performed to further refine and fine-tune one or more algorithms for determining one or more respective fluid properties.

Notwithstanding the embodiment of the hand-held analysis device 300 described above, additions and/or refinements to the device are contemplated. For example, although the main processor 314 has been explained with respect to specific functionality, it can be appreciated that tie main processor is capable of performing a wide variety of additional operations other than those described above. Further, the type, model and specifications of the various components of the hand-held device can vary from one embodiment to another. Additionally, the communication interfaces and connections with respect to the various components described above are exemplary and as such variations are contemplated and considered within the scope of the present invention. Components other than described above can also be used in conjunction with the device 300. The shapes, sizes, material of construction and the orientation of the various components described above can vary depending upon the embodiment. Further, despite any method(s) being outlined in a step-by-step sequence, the completion of acts or steps in a particular chronological order is not mandatory. Any modification, rearrangement, combination, reordering, or the like, of acts or steps is contemplated and considered within the scope of the description and claims. It is specifically intended that the present invention not be limited to the embodiments and illustrations contained herein, but include modified forms of those embodiments including portions of the embodiments and combinations of elements of different embodiments.

The following United States patent documents are hereby incorporated by reference in their entirety herein, U.S. Pat. No. 6,278,281; U.S. Pat. No. 6,377,052; U.S. Pat. No. 6,380,746; U.S. Pat. No. 6,839,620; U.S. Pat. No. 6,844,745; U.S. Pat. No. 6,850,865; U.S. Pat. No. 6,989,680; U.S. Pat. No. 7,043,372; U.S. Pat. No. 7,049,831; U.S. Pat. No. 7,078,910; U.S. Patent Appl. No. 2005/0110503; and U.S. Patent Appl. No. 2006/0214671.

Although the invention has been described in detail with reference to preferred embodiments, variations and modifications exist within the scope and spirit of the invention as described and defined in the following claims.

What is claimed is:

1. A sample cell for use in conjunction with an impedance spectroscopy analysis device having two electrodes extending therefrom, the sample cell attachable to and detachable from the analysis device, the sample cell comprising,
a housing having an input port for receiving a fluid sample to be tested,
two spaced apart parallel plates within the housing and in contact with a fluid sample,
wherein when the sample cell is attached to the analysis device, each of the two electrodes contacts a respective one of the plates such that an excitation signal can be provided from the analysis device via the electrodes and the plates to excite the fluid sample, and a response signal indicative of the fluid sample can be communicated via the plates and the electrodes to the analysis device.

2. The sample cell of claim 1, further including a gasket between the two plates.

3. The sample cell of claim 1, wherein the housing includes two cutouts such that each of the electrodes contacts a respective one of the plates though a respective cutout.

4. The sample cell of claim 1, further including an output port formed in the housing for allowing air to escape when the sample cell is being filled.

5. The sample cell of claim 1, further including a circuit for storing at least one of a specific identifier and a calibration parameter of the sample cell.

6. The sample cell of claim 5, further including a temperature sensor for providing a temperature signal indicative of the temperature of the sample fluid to the analysis device.

7. The sample cell of claim 6, wherein the temperature sensor is a thermistor.

8. The sample cell of claim 1, wherein upon plugging the sample cell into the analysis device, a main processor of the analysis device determines whether the sample cell has previously been used and facilitates data collection only if the sample cell has not been previously used.

9. A sample cell for use in conjunction with an impedance spectroscopy analysis device having two electrodes extending therefrom, the sample cell attachable to and detachable from the analysis device, the sample cell comprising,
a housing having an input port for receiving a fluid sample to be tested,
two spaced apart parallel plates within the housing forming with the housing a reservoir for the fluid sample,
a circuit including a memory to store a predetermined identifier specific to the sample cell,
wherein when the sample cell is attached to the analysis device, the circuit is in electrical communication with the analysis device and the predetermined identifier is communicated to the analysis device, and each of the two electrodes contacts a respective one of the plates such that excitation signals from the analysis device can be applied via the electrodes and the plates to the fluid sample and response signals indicative of the fluid sample can be received by the analysis device via the electrodes and the plates to measure and determine a property of the fluid sample.

10. The sample cell of claim 9, wherein when the sample cell is attached to the analysis device, the analysis device determines whether the sample cell has previously been used and facilitates data collection only if the sample cell has not been previously used.

11. The sample cell of claim 9, further including a gasket between the two plates.

12. The sample cell of claim 9, wherein the housing includes two cutouts such that each of the electrodes contacts a respective one of the plates though a respective cutout.

13. The sample cell of claim 9, further including an output port formed in the housing and in communication with the reservoir for allowing air to escape when the sample cell is filled.

14. The sample cell of claim 9, wherein the circuit also stores one or more calibration parameters of the sample cell.

15. The sample cell of claim 9, further including a temperature sensor for measuring a temperature of the fluid sample, and providing a temperature signal indicative of the temperature to the analysis device.

16. The sample cell of claim 15, wherein the temperature sensor is a thermistor.

17. The sample cell of claim 9, wherein the circuit includes a memory device in communication with a microprocessor.

18. A sample cell for use in conjunction with an impedance spectroscopy analysis device having two electrodes extending therefrom, the sample cell attachable to the analysis device, the sample cell comprising,
a housing including a first housing portion having an input port for receiving a fluid sample to be tested and a second housing portion, wherein each housing portion includes a cutout,
a circuit for storing one or more parameters,
two spaced apart parallel plates within the housing forming with the housing a reservoir for the fluid sample, and
wherein when the sample cell is attached to the analysis device, each of the two electrodes contacts a respective one of the plates through a respective cutout and the circuit is in electrical communication with the analysis device.

19. The sample cell of claim 18, further wherein when the sample cell is attached to the analysis device, the analysis device determines whether the sample cell has previously been used and facilitates data collection only if the sample cell has not been previously used.
